(19) United States
(12) Patent Application Publication
(10) Pub. No.: US 2017/0207102 A1
(43) Pub. Date: Jul. 20, 2017

(54) SEMICONDUCTOR MANUFACTURING APPARATUS AND SEMICONDUCTOR MANUFACTURING METHOD

(71) Applicant: Kabushiki Kaisha Toshiba, Minato-ku (JP)

(72) Inventor: Yuuko JIMMA, Yokkaichi (JP)

(73) Assignee: Kabushiki Kaisha Toshiba, Minato-ku (JP)

(21) Appl. No.: 15/264,794

(22) Filed: Sep. 14, 2016

Related U.S. Application Data
(60) Provisional application No. 62/279,101, filed on Jan. 15, 2016.

(51) Int. Cl. H01L 21/311; H01L 21/027; H01L 21/3105; C23C 16/52; H01L 21/28; H01L 27/115; C23C 16/50; H01L 21/02; H01L 21/768

(52) U.S. Cl. CPC H01L 21/31116; H01L 21/02274; H01L 21/0273; H01L 21/31144; H01L 21/31053; H01L 21/76816; H01L 21/76819; H01L 21/76877; H01L 21/28282; H01L 27/1157; H01L 27/11582; C23C 16/50; C23C 16/52

(57) ABSTRACT

A semiconductor manufacturing apparatus according to an embodiment includes a reaction portion, a discharge portion, a mounting portion, a first member, and a second member. The reaction portion enables a reactant gas processing a substrate to be introduced therein. The discharge portion is connected to the reaction portion. The mounting portion is located between the reaction portion and the discharge portion and enables the substrate to be mounted thereon. The first member is located around the mounting portion and has a plurality of through holes that cause the reaction portion and the discharge portion to be communicated with each other. The second member can change respective opening areas of the through holes.

### CROSS REFERENCE TO RELATED APPLICATIONS

This application is based upon and claims the benefit of priority from the prior U.S. Provisional Patent Application No. 62/279,101 filed on Jan. 15, 2016, the entire contents of which are incorporated herein by reference.

### FIELD

The embodiments of the present invention relate to a semiconductor manufacturing apparatus and a semiconductor manufacturing method.

### BACKGROUND

In a manufacturing process of a semiconductor device, after a film is formed on a wafer mounted on a mounting stand in a chamber, an etching gas is introduced into the chamber and the film is processed into a predetermined pattern by dry etching. To suppress reactive products resulting from the dry etching from adhering onto the wafer, the reactive products in the chamber are discharged during the dry etching together with the gas through a plurality of discharge holes that cause the chamber and a gas discharge passage to be communicated with each other.

Conventionally, a plurality of discharge holes of the same size are positioned on an outer circumference of the mounting stand. Therefore, the discharge holes can uniform discharge amounts (that is, elimination amounts) of the reactive products per unit time over the entire circumference of the wafer.

However, deposition amounts of the reactive products within a plane of the wafer do not become uniform due to a factor such as the shape of a pattern or non-uniform film thicknesses within the plane of the wafer unique to a manufacturing apparatus. Accordingly, if the discharge amounts of the reactive products over the entire circumference of the wafer are uniformed, adhesion amounts of the reactive products vary in the plane of the wafer and consequently uniformity in the film thickness within the plane of the wafer (hereinafter, also “in-plane uniformity”) is deteriorated.

### BRIEF DESCRIPTION OF THE DRAWINGS

FIG. 1 is a schematic sectional view showing a semiconductor manufacturing apparatus according to an embodiment;

FIG. 2 is a sectional view along a line II-II in FIG. 1;

FIG. 3 is a flowchart showing a semiconductor manufacturing method according to the embodiment; and

FIG. 4A is a schematic diagram showing second members before etching is started as an example of the semiconductor manufacturing method according to the present embodiment, and FIG. 4B is a schematic diagram showing the second members after etching is started.

### DETAILED DESCRIPTION

A semiconductor manufacturing apparatus according to an embodiment includes a reaction portion, a discharge portion, a mounting portion, a first member, and a second member. The reaction portion enables a reactant gas processing a substrate to be introduced therein. The discharge portion is connected to the reaction portion. The mounting portion is located between the reaction portion and the discharge portion and enables the substrate to be mounted thereon. The first member is located around the mounting portion and has a plurality of through holes that cause the reaction portion and the discharge portion to be communicated with each other. The second member can change respective opening areas of the through holes.

Embodiments will now be explained with reference to the accompanying drawings. The present invention is not limited to the embodiments.

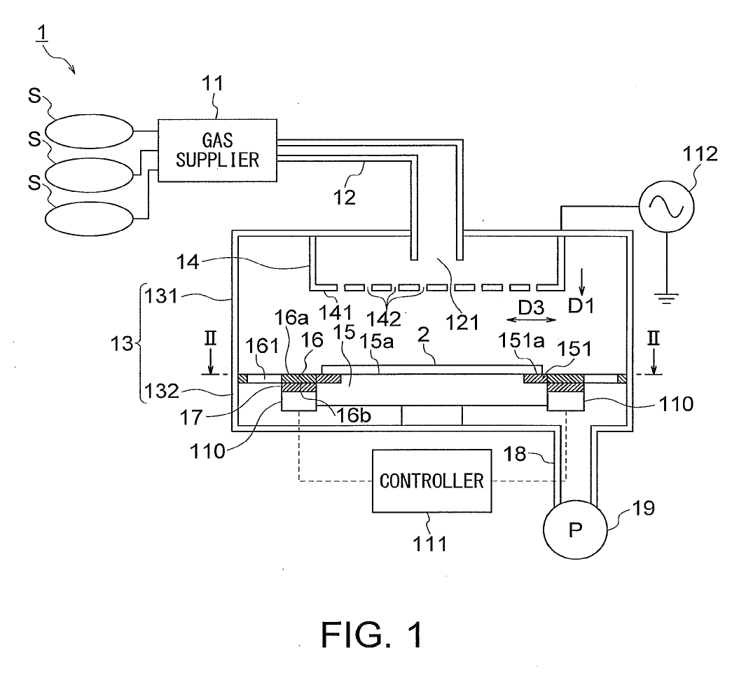

FIG. 1 is a schematic sectional view showing a semiconductor manufacturing apparatus 1 according to an embodiment. The semiconductor manufacturing apparatus 1 shown in FIG. 1 is a single-wafer-processing plasma CVD apparatus.

As shown in FIG. 1, the semiconductor manufacturing apparatus 1 includes a gas supplier 11, a gas introduction passage 12, a chamber 13, an upper electrode 14, a lower electrode 15 being an example of a mounting portion, a first member 16, a plurality of second members 17, a discharge passage 18, and a pump 19 in this order from a gas upstream side. The chamber 13 includes a reaction portion 131 and a discharge portion 132 connected to the reaction portion 131. The semiconductor manufacturing apparatus 1 also includes a plurality of moving devices 110, a controller 111, and a high-frequency power source 112.

The gas supplier 11 is connected to gas sources S of plural types of reactant gases that process a semiconductor substrate 2. For formation of a film on the semiconductor substrate 2 or dry etching of the film on the semiconductor substrate 2, the gas supplier 11 supplies a source gas including components of the film or an etching gas (that is, first reactant gas) to be used for the dry etching into the chamber 13. The gas supplier 11 can supply other gases such as a plasma diluent gas and a cleaning gas. The gas supplier 11 can be constituted of elements such as a mass flow controller and a valve. Supply of the gases by the gas supplier 11 can be controlled by the controller 111.

The gas introduction passage 12 connects the gas supplier 11 and the reaction portion 131 of the chamber 13 to each other.

The reaction portion 131 enables the gases to be introduced therein through the gas introduction passage 12.

The upper electrode 14 (that is, a showerhead) surrounds a certain region including an outlet port 121 of the gas introduction passage 12 in the chamber 13. A bottom wall 141 of the upper electrode 14 has a plurality of through holes 142. The gases introduced into the chamber 13 are introduced into the upper electrode 14 and then are ejected through the through holes 142 toward the lower electrode 15. Due to passing through the through holes 142, the gases can be supplied to the semiconductor substrate 2 in a diffused state. By diffusing the gases, in-plane uniformity at the time of film formation on the semiconductor substrate 2 can be enhanced. The upper electrode 14 can have a diffuser panel therein.

The lower electrode 15 is placed between the reaction portion 131 and the discharge portion 132 to face the upper electrode 14 below D1 thereof. The lower electrode 15 can have the semiconductor substrate 2 mounted on an upper surface 15a. An annular dummy ring 151 concentric with the upper surface 15a is entirely circumscribing the upper surface 15a. An upper surface 151a of the dummy ring 151 can be flush with the upper surface 15a of the lower electrode 15. The dummy ring 151 holds a peripheral portion of the semiconductor substrate 2 from below. A peripheral portion of the dummy ring 151 is exposed in the chamber 13 at the time of dry etching. So as not to be ground during the dry etching, a material of the dummy ring 151 preferably has a resistance property against the dry etching. The lower electrode 15 can incorporate a heater therein and heat the mounted semiconductor substrate 2 to a predetermined temperature using the heater. Heating of the semiconductor substrate 2 can increase the film formation rate.

The first member 16 is placed in the chamber 13. Specifically, the first member 16 is provided around the lower electrode 15 to separate the reaction portion 131 and the discharge portion 132 from each other. More specifically, the first member 16 has an annular plate shape and is in contact with the dummy ring 15 at an inner end thereof in a radial direction D3 and in contact with an inner wall of the chamber 13 at an outer end thereof in the radial direction D3.

An upper surface 16a of the first member 16 being an example of a first surface on the side of the reaction portion 131 can be flush with the upper surface 15a of the lower electrode 15 and the upper surface 151a of the dummy ring 151 or below D1 these surfaces 15a and 151a. Accordingly, the upper surface 16a of the first member 16 is located below D1 an upper surface of the semiconductor substrate 2 on the lower electrode 15 and accordingly discharge of reactive products on the semiconductor substrate 2 through a plurality of through holes 161 of the first member 16 described later can be achieved efficiently.

The first member 16 has the through holes 161 that cause the reaction portion 131 and the discharge portion 132 to be communicated with each other. Through the through holes 161, gases in the reaction portion 131 can be discharged to the discharge portion 132 and the discharge passage 18 downstream thereof.

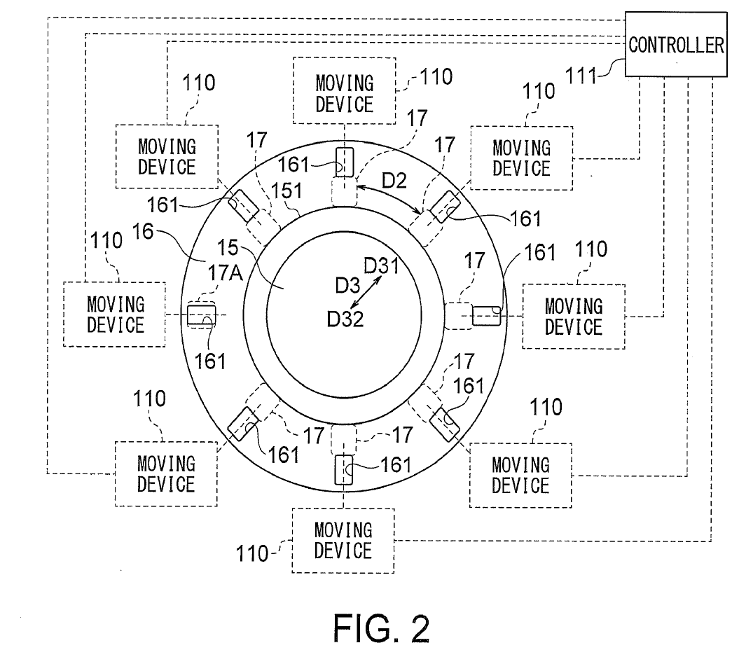

FIG. 2 is a sectional view along a line II-II in FIG. 1. In an example of FIG. 2, the through holes 161 are positioned at equal intervals in a circumferential direction D2 of the first member 16. The through holes 161 have a cross-section in a substantially rectangular shape extending in the radial direction D3. Respective shapes, areas, and distances from the center of the lower electrode 15 of the through holes 161 are the same. Because the through holes 16 are thus positioned uniformly, the semiconductor manufacturing apparatus 1 can be applied to manufacturing of various types of semiconductor devices.

The second members 17 as many as the through holes 16 are placed on a lower surface 16b of the first member 16 being an example of a second surface on the side of the discharge portion 132 to correspond to the through holes 16.

The second members 17 are placed on the first member 16 to be capable of moving within a moving range between a first position where the corresponding through holes 161 are entirely opened, that is, exposed and a second position where the corresponding through holes 161 are entirely shielded.

In FIG. 2, all the second members 17 except for one second member 17A are shown at the first position radially inward D32 with respect to the corresponding through holes 161. The second member 17A is shown at the second position where the corresponding through hole 161 is entirely shielded.

The second members 17 in FIG. 2 are capable of reciprocating within the moving ranges in the radial direction D3 from the first position to the second position. The second position is located radially outward D31 with respect to the first position. The second members 17 have a substantially rectangular shape larger in the cross-section than the through holes 161 to enable the through holes 161 to be entirely shielded at the second position. The moving range in FIG. 2 can include a position radially outward D31 with respect to the second position.

The second members 17 can change opening areas of the corresponding through holes 161, respectively. The opening areas of the through holes 161 are areas not shielded by the second members 17 in areas of cross-sections (hereinafter, also “cross-sectional areas of the through holes 161”) obtained by cutting the through holes 161 along a surface perpendicular to the pass-through direction.

It can be said that the second members 17 can change shield areas of the respective through holes 161. The shield areas are areas shielded by the second members 17 in the cross-sectional areas of the through holes 161, respectively.

When the second members 17 are located at the first position, the opening areas are the cross-sectional areas of the through holes 161 being the maximum value. When the second members 17 are located at the second position, the opening areas are zero being the minimum value.

To open, that is, to expose the through holes 161 by individual opening areas for the respective through holes 161, the second members 17 are coupled to the corresponding moving devices 110, respectively. The moving devices 110 are placed as many as the second members 17 to correspond to the second members 17. The moving devices 110 move the corresponding second members 17 in the radial direction D3 for changing the opening areas.

More specifically, the moving devices 110 move the corresponding second members 17 radially outward D31 to decrease the opening areas and move the corresponding second members 17 radially inward D32 to increase the opening areas.

By moving in the radial direction D3, the second members can open the through holes 161 by opening areas corresponding to the respective moving amounts. Because of being capable of changing the opening areas in the radial direction D3, the second members 17 can efficiently adjust the discharge amount of reactive products resulting from dry etching, which will be explained later.

The specific mode of the moving devices 110 is not particularly limited and the moving devices 110 each can include, for example, a motor and a power conversion member, such as a rack gear, that converts a rotational motion of the motor into a translational motion of the corresponding second member 17.

The moving devices 110 are connected to the controller 111 and move the corresponding second members 17 by moving amounts according to instructions from the controller 111, respectively.

The controller 111 controls movements of the moving devices 110. In a memory area of the controller 111, the moving amounts of the second members 17 are set in advance for the respective moving devices 110. The specific mode of the moving amounts is not particularly limited and can be, for example, the number of rotations of the motor.

The controller 111 instructs the moving devices 110 on movements by the moving amounts individually set for the respective moving devices 110. The moving devices 110 move the second members 17 by the instructed moving amounts to cause the second members 17 to open the through holes 161 by opening areas corresponding to the moving amounts. In this way, the second members 17 can open the through holes 161 by the individual opening areas for the respective through holes 161.

The moving amounts of the second members 17 set in the controller 111 are moving amounts corresponding to a tendency of deposition amounts of the reactive products resulting from dry etching of a film within the plane of the semiconductor substrate 2. More specifically, the moving amounts of the second members 17 are moving amounts for adjusting the shield areas of the through holes 161 to cause adhesion amounts of the reactive products within the plane of the semiconductor substrate 2 to be nearly uniform.

With the configuration described above, the second members 17 can open the through holes 161 by the individual opening areas for the respective through holes 161. Accordingly, the discharge amounts of the reactive products through the through holes 161 can be adjusted to reduce variation in the deposition amounts of the reactive products due to a factor such as the shape of the pattern on the semiconductor substrate 2 or the in-plane non-uniformity in the film thickness unique to the semiconductor manufacturing apparatus 1. This can improve the in-plane uniformity after the dry etching.

As shown in FIG. 1, the discharge passage 18 extends from the discharge portion 132 to the pump 19. The discharge passage 18 causes the gases and the reactive products discharged from the chamber 13 to flow to a downstream side.

The pump 19 is placed on the discharge passage 18. The pump 19 performs discharge from the inside of the reaction portion 131 via the discharge portion 132 and the discharge passage 18 to discharge the gases and the reactive products from the reaction portion 131. The pump 19 performs discharge from the inside of the reaction portion 131 also at the time of film formation on the semiconductor substrate 2 by plasma processing. The pump 19 can be, for example, a dry pump. The operation of the pump 19 can be controlled by the controller 111.

The high-frequency power source 112 is connected to the upper electrode 14. The high-frequency power source 112 applies high-frequency power to the upper electrode 14. Application of the high-frequency power causes the upper electrode 14 to capacitively couple to the lower electrode 15 to supply power into the reaction portion 131. In response to supply of an etching gas into the reaction portion 131 supplied with the power in a vacuum state, dry etching of the film according to a resist pattern on the semiconductor substrate 2 is performed. The operation of the high-frequency power source 112 can be controlled by the controller 111.

### (Semiconductor Manufacturing Method)

A semiconductor manufacturing method to which the semiconductor manufacturing apparatus 1 shown in FIG. 1 is applied is explained next.

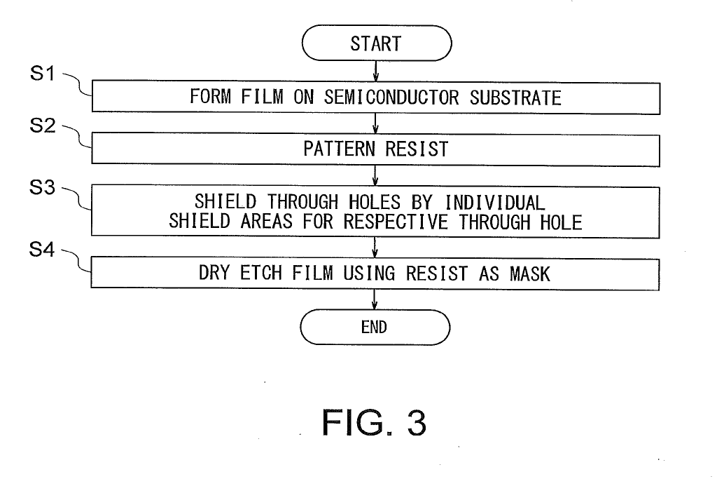

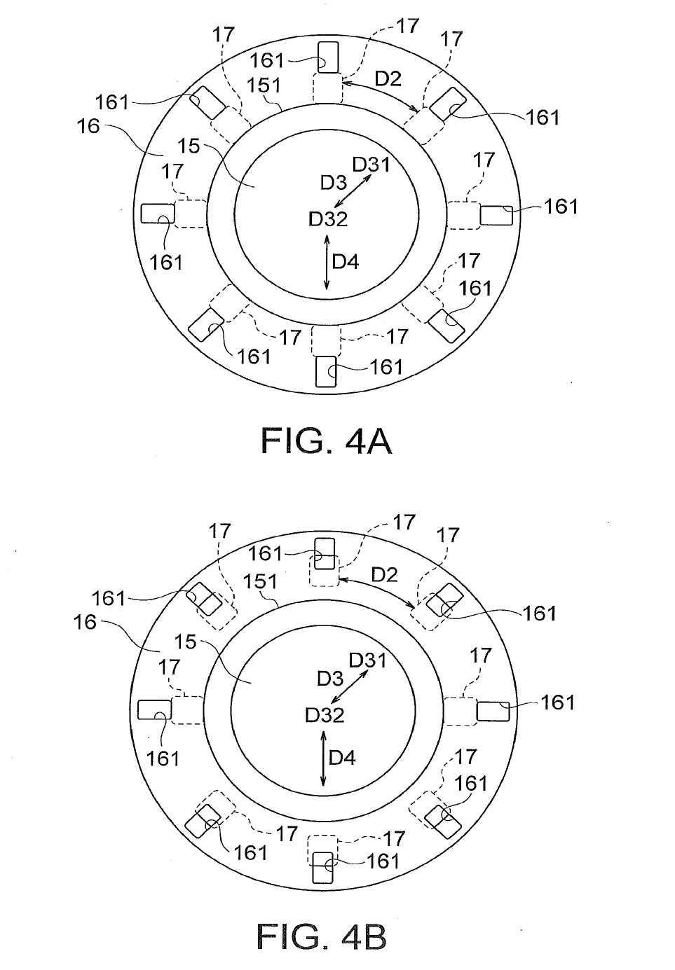

FIG. 3 is a flowchart showing a semiconductor manufacturing method according to the present embodiment. FIG. 4A is a schematic diagram showing the second members 17 before etching is started as an example of the semiconductor manufacturing method according to the present embodiment.

In an initial state of FIG. 3, all the second members 17 are in a retracted state at the first position radially inward D32 with respect to the through holes 161, as shown in FIG. 4A. A direction D4 in FIG. 4A is an extension direction of a line pattern to be formed by dry etching.

When a line pattern is formed on the semiconductor substrate 2, deposition amounts of reactive products on edge portions located in a direction orthogonal to the extension direction D4 of the line pattern in the peripheral edge of the semiconductor substrate 2 tend to be larger than those of the reactive products on edge portions located in the extension direction D4.

In the initial state of FIG. 3, to enhance the in-plane uniformity of the line pattern according to this in-plane tendency in the deposition amounts of the reactive products, the moving amounts of the second members 17 are set in advance in the memory area of the controller 111 individually for the respective moving devices 110.

Specifically, the moving amounts of the second members 17 set in the controller 111 are moving amounts that cause the opening areas of the through holes 161 located in the direction orthogonal to the extension direction D4 with respect to the semiconductor substrate 2 to be larger than the opening areas of the through holes 161 located in the extension direction D4 with respect to the semiconductor substrate 2. That is, the moving amounts of the second members 17 set in the controller 111 are larger on sides in the extension direction D4 and smaller on sides in the orthogonal direction to the extension direction D4. The moving amounts of the second members 17 set in the controller 111 are also moving amounts that cause the shield areas of the through holes 161 located in the orthogonal direction to the extension direction D4 with respect to the semiconductor substrate 2 to be smaller than the shield areas of the through holes 161 located in the extension direction D4 with respect to the semiconductor substrate 2.

Because the second members 17 are placed radially inward D32 with respect to the through holes 161, open parts of the through holes 161 are more distant from the semiconductor substrate 2 as the moving amounts of the second members 17 radially outward D31 are larger. Conversely, as the moving amounts of the second members 17 radially outward D31 are smaller, the open parts of the through holes 161 are closer to the semiconductor substrate 2. Therefore, it can also be said that the moving amounts of the second members 17 set in the controller 111 are moving amounts that cause the through holes 161 on the sides in the orthogonal direction to the extension direction D4 to be closer to the semiconductor substrate 2 than the through holes 161 on the sides in the extension direction D4 are caused to be.

The moving amounts of the second members 17 can be set based on results of experiments or simulations.

In the initial state of FIG. 3, a film or a pattern in a lower layer can have been already formed on the semiconductor substrate 2.

From the initial state described above, film formation on the semiconductor substrate 2 is first performed as shown in FIG. 3 (Step S1). At the time of film formation, in a state where air in the reaction portion 131 is discharged by the pump 19 to obtain a vacuum state and also power is supplied to the reaction portion 131 by the high-frequency power source 112, a source gas and a diluent gas are supplied from the gas supplier 11 into the reaction portion 131. The source gas supplied into the reaction portion 131 is transformed into plasma (disassociated) due to the power to generate film formation species. The generated film formation species react on the semiconductor substrate 2, whereby a film is grown on the semiconductor substrate 2.

After the film formation, a resist is patterned on the film (Step S2). The resist can be patterned, for example, by photolithography.

FIG. 4B is a schematic diagram showing the second members 17 after etching is started. After the resist is patterned, the through holes 161 are shielded by the second members 17 by the individual shield areas for the respective through holes 161 as shown in FIG. 4B (Step S3). That is, the through holes 161 are opened by the individual opening areas for the respective through holes 161. At the time of shielding the through holes 161, the controller 111 instructs the moving devices 110 on movements by the moving amounts set in advance.

The moving devices 110 move the second members 17 radially outward D31 by the moving amounts instructed by the controller 111. By moving radially outward D31, the second members 17 shield the corresponding through holes 161 by the shield areas corresponding to the moving amounts.

Specifically, the second members 17 shield the through holes 161 located in the extension direction D4 with respect to the semiconductor substrate 2 by larger shield areas than those of the through holes 161 located in the orthogonal direction to the extension direction D4 with respect to the semiconductor substrate 2.

After the through holes 161 are shielded, dry etching to grind the film with an etching gas using the resist as a mask is performed (Step S4). In the dry etching, in a state where the gases in the reaction portion 131 are discharged by the pump 19 to obtain the vacuum state and also power is supplied to the reaction portion 131 by the high-frequency power source 112, the etching gas is supplied from the gas supplier 11 into the reaction portion 131. The etching gas supplied into the reaction portion 131 is disassociated by the power, whereby an etchant, that is, etching species are generated. The generated etchant reacts with a part of the film exposed from the resist on the semiconductor substrate 2, so that the part of the film according to the resist pattern is fallen away from the semiconductor substrate 2 as reactive products.

The reactive products are discharged from the reaction portion 131 into the discharge portion 132 through the through holes 161 by suction power of the pump 19. The reactive products discharged into the discharge portion 132 are discharged into the discharge passage 18.

If the sizes of the through holes 161 are set to be the same at the time of formation of a line pattern on the semiconductor substrate 2, the discharge amounts of the reactive products through the respective through holes 161 per unit time are uniform. In this case, due to the uniform discharge amounts of the reactive products through the respective through holes 161, the adhesion amounts (that is, remaining amounts) of the reactive products on edge portions located in the orthogonal direction to the extension direction D4 of the line pattern in the peripheral edge of the semiconductor substrate 2 become excessive. Such non-uniformity in the adhesion amounts on the peripheral edge occurs also in regions on an inner side of the peripheral edge and many reactive products adhere also to the inner side of the peripheral edge on the semiconductor substrate 2 on the sides in the orthogonal direction to the extension direction D4. As a result, the in-plane uniformity of the line pattern is degraded.

In contrast thereto, in the present embodiment, the shield areas of the through holes 161 located in the orthogonal direction to the extension direction D4 with respect to the semiconductor substrate 2 are decreased (that is, the opening areas are increased) to enable more reactive products to be discharged in the orthogonal direction to the extension direction D4.

Accordingly, the reactive products that are deposited more on the semiconductor substrate 2 on the sides in the orthogonal direction to the extension direction D4 can be sufficiently eliminated.

A greater influence is exerted on the discharge amounts of the reactive products by the width of the through holes 161 in the radial direction D3 than the width of the through holes 161 in the circumferential direction D2. Because the opening areas can be adjusted in the radial direction D3 in the present embodiment, the discharge amounts of the reactive products can be adjusted effectively.

The deposition amounts of the reactive products are influenced also by the positions (that is, the distances) of the through holes 161 with respect to the semiconductor substrate 2. Specifically, as the positions of the through holes 161 are closer to the semiconductor substrate 2, the discharge amounts of the reactive products are increased to decrease the adhesion amounts. As the positions of the through holes 161 are farther from the semiconductor substrate 2, the discharge amounts of the reactive products are decreased to increase the adhesion amounts. In the present embodiment, the shield areas are increased by moving the second members 17 radially outward D31 and the shield areas are decreased by moving the second members 17 radially inward D32. In this way, the positions of the through holes 161 (that is, the open parts) with respect to the semiconductor substrate 2 can also be adjusted as well as the shield areas. Specifically, the open parts of the through holes 161 on the sides in the orthogonal direction to the extension direction D4 can be brought closer to the semiconductor substrate 2 to enable more reactive products to be discharged in the orthogonal direction to the extension direction D4. Accordingly, the discharge amounts of the reactive products can be adjusted more effectively.

Furthermore, because the second members 17 are placed on the lower surface 16b of the first member 16, that is, outside the reaction portion 131, influences of the second members 17 on the film formation or the dry etching can be avoided more than in a case where the second members 17 are placed on the upper surface 16a, that is, in the reaction portion 131.

As described above, according to the present embodiment, the through holes 161 are opened by the individual opening areas for the respective through holes 161. This enables adjustment of the discharge amounts of the reactive products through the through holes 161 to reduce the non-uniformity in the deposition amounts of the reactive products caused by the pattern shape, the process, the in-plane non-uniformity in the film thickness, or the like. As a result, the in-plane uniformity of the pattern can be enhanced.

While the moving devices 110 move the second members 17 in the radial direction D3 in FIG. 4, the moving devices 110 can move the second members 17 in the circumferential direction D2 (see FIG. 2) instead of the radial direction D3.

The present embodiment can be applied to formation of various line patterns. For example, the line pattern can be a pattern of a semiconductor storage device such as a pattern of memory cells in a two-dimensional flash memory or a pattern of upper select gates in a three-dimensional stack flash memory. The present embodiment can also be applied to enhance the in-plane uniformity of patterns other than the line pattern.

In the embodiment described above, the opening areas of the through holes 161 are adjusted to adjust the discharge amounts of the reactive products resulting from dry etching. However, the present embodiment can alternatively be applied to enhance the in-plane uniformity at the time of film formation. For example, in a manufacturing process of a three-dimensional stack NAND flash memory, a stack film is formed by stacking insulating films and silicon nitride films alternately and repeatedly. In the course of forming the stack film, the opening areas of the through holes 161 can be changed using the second members 17 for respective layers according to in-plane tendencies in the film thickness of the respective layers so as to enhance the in-plane uniformity.

In the embodiment described above, semiconductor devices are manufactured by plasma CVD. However, the present embodiment can also be applied to manufacture semiconductor devices using thermal CVD, MO (Metal Organic) CVD, or LP (Low Pressure) CVD.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a reaction portion enabling a reactant gas processing a substrate to be introduced therein;
a discharge portion connected to the reaction portion;
a mounting portion located between the reaction portion and the discharge portion and enabling the substrate to be mounted thereon;
a first member located around the mounting portion and having a plurality of through holes causing the reaction portion and the discharge portion to be communicated with each other; and
a second member capable of changing respective opening areas of the through holes.

2. The apparatus of claim 1, comprising:
a moving device moving the second member in a direction to change the opening areas; and
a controller controlling a movement of the second member, wherein
the reactant gas includes a first reactant gas grinding a film on the substrate, and
the controller executes control to move the second member by a moving amount according to a tendency of a deposition amount of reactive products resulting from grinding of the film within a plane of the substrate.

3. The apparatus of claim 2, wherein the moving amount is a moving amount that causes opening areas of ones of the through holes located in a direction orthogonal to an extension direction of a line pattern obtained by grinding the film with respect to the substrate to be larger than opening areas of ones of the through holes located in the extension direction with respect to the substrate.

4. The apparatus of claim 1, wherein the second member can change the opening areas in a radial direction by moving in a radial direction of the substrate.

5. The apparatus of claim 2, wherein the second member can change the opening areas in a radial direction by moving in a radial direction of the substrate.

6. The apparatus of claim 3, wherein the second member can change the opening areas in a radial direction by moving in a radial direction of the substrate.

7. The apparatus of claim 4, wherein the second member reduces the opening areas by moving outward in the radial direction.

8. The apparatus of claim 5, wherein the second member reduces the opening areas by moving outward in the radial direction.

9. The apparatus of claim 6, wherein the second member reduces the opening areas by moving outward in the radial direction.

10. The apparatus of claim 1, wherein
the first member has a first surface on a side of the reaction portion, and a second surface opposite to the first surface on a side of the discharge portion, and
the second member is placed on the second surface.

11. The apparatus of claim 2, wherein
the first member has a first surface on a side of the reaction portion, and a second surface opposite to the first surface on a side of the discharge portion, and
the second member is placed on the second surface.

12. The apparatus of claim 3, wherein
the first member has a first surface on a side of the reaction portion, and a second surface opposite to the first surface on a side of the discharge portion, and
the second member is placed on the second surface.

13. The apparatus of claim 4, wherein
the first member has a first surface on a side of the reaction portion, and a second surface opposite to the first surface on a side of the discharge portion, and
the second member is placed on the second surface.

14. The apparatus of claim 7, wherein
the first member has a first surface on a side of the reaction portion, and a second surface opposite to the first surface on a side of the discharge portion, and
the second member is placed on the second surface.

15. The apparatus of claim 1, wherein the through holes have a cross-section extending in the radial direction.

16. The apparatus of claim 1, wherein
the first member has a first surface on a side of the reaction portion, and a second surface opposite to the first surface on a side of the discharge portion, and
the first face is positioned below an upper surface of the substrate.

17. The apparatus of claim 1, wherein the second members as many as the through holes are placed to correspond to the through holes.

18. The apparatus of claim 1, wherein the through holes are located at equal intervals in a circumferential direction.

19. A semiconductor manufacturing method comprising:
in a semiconductor manufacturing apparatus comprising a reaction portion enabling a reactant gas processing a substrate to be introduced therein, a discharge portion connected to the reaction portion, a mounting portion located between the reaction portion and the discharge portion and enabling the substrate to be mounted thereon, a first member located around the mounting portion and having a plurality of through holes causing the reaction portion and the discharge portion to be communicated with each other, and a second member capable of changing respective opening areas of the through holes, opening the through holes using the second member by individual opening areas for respective through holes; and
after the through holes are opened, introducing the gas into the reaction portion to process the substrate, and discharging reactive products resulting from processing of the substrate through the through holes opened by the second member.

20. The method of claim 19, wherein
the processing of the substrate comprises grinding of a film on the substrate, and
the opening of the through holes comprises moving the second member by a moving amount according to a tendency of a deposition amount of reactive products within a plane of the substrate.
